(19) United States
(12) Patent Application Publication
(10) Pub. No.: US 2026/0142641 A1
(43) Pub. Date: May 21, 2026

(54) ACOUSTIC WAVE DEVICE INCLUDING RESONATORS FORMED ON PIEZOELECTRIC SUBSTRATE OF DIFFERENT HEIGHTS AND METHOD FOR MANUFACTURING THE SAME

(71) Applicant: WISOL CO., LTD., Osan-si (KR)

(72) Inventors: Sung Hyun LEE, Osan-si (KR); Sang Hoon MYEONG, Osan-si (KR); Sang Ki BAE, Osan-si (KR); Chang Min LEE, Osan-si (KR)

(73) Assignee: WISOL CO., LTD., Osan-si (KR)

(21) Appl. No.: 19/379,565

(22) Filed: Nov. 4, 2025

(30) Foreign Application Priority Data
Nov. 18, 2024 (KR) 10-2024-0163967

(51) Int. Cl. H03H 9/02; H03H 3/08; H03H 9/25

(52) U.S. Cl. CPC H03H 9/02992; H03H 3/08; H03H 9/25

(57) ABSTRACT

A surface acoustic wave (SAW) device including resonators formed on piezoelectric substrates of different heights and a method for manufacturing the same are provided. The SAW device includes: a support substrate; a piezoelectric substrate disposed on the support substrate and including a first region, a second region, and a step region disposed between the first and second regions; a first resonator formed on the first region of the piezoelectric substrate; a second resonator formed on the second region of the piezoelectric substrate; and a bus bar formed on the step region of the piezoelectric substrate. The piezoelectric substrate has different thicknesses between the first and second regions, and a surface of the step region connecting the first and second regions forms an angle of 60 degrees or less with the top surface of the first or second region.

### FIELD OF THE INVENTION

The present invention relates to an acoustic wave device including resonators formed on piezoelectric substrates having different heights and a method for manufacturing the same, and more particularly, to an acoustic wave device and a method for manufacturing the same, in which a piezoelectric substrate disposed on a support substrate has different thicknesses for respective resonators to facilitate adjustment of an electromechanical coupling coefficient (k²), and a step region defined between piezoelectric films of different thicknesses is formed at a predetermined angle to improve the reliability of a metal layer formed thereon.

### Background of the Related Art

A surface acoustic wave (SAW) refers to a wave that propagates along the surface of an elastic solid.

Such a surface acoustic wave propagates with its energy concentrated near the surface and corresponds to a mechanical wave.

A surface acoustic wave device is an electromechanical component utilizing the interaction between the surface acoustic wave and semiconductor conduction electrons, and it makes use of the surface acoustic wave transmitted along the surface of a piezoelectric crystal.

These devices can be applied to a wide range of industrial applications such as sensors, oscillators, and filters. They offer advantages including compactness, light weight, robustness, stability, sensitivity, low cost, and real-time response capability.

Meanwhile, Patent Document 1 discloses a surface acoustic wave device comprising a piezoelectric thin film having IDT electrodes and another piezoelectric thin film having reflectors on both sides of the IDT electrodes, wherein the two piezoelectric films have different thicknesses.

### Technical problem

The technical problem to be solved by the present invention is to provide an acoustic wave device in which a piezoelectric substrate disposed on a support substrate has different thicknesses for respective resonators to facilitate adjustment of the electromechanical coupling coefficient (k²), and a step region defined as a boundary between piezoelectric thin films of different thicknesses is formed at a predetermined angle to improve the reliability of a metal layer formed thereon.

The technical problems of the present invention are not limited to those mentioned above, and other technical problems that are not explicitly described herein will be apparent to those skilled in the art from the following detailed description of the invention.

### Technical solution

According to an embodiment of the present invention, an acoustic wave device including resonators formed on piezoelectric substrates having different heights comprises: a support substrate; a piezoelectric substrate disposed on the support substrate and including a first region, a second region, and a step region disposed between the first and second regions; a first resonator formed on the first region of the piezoelectric substrate and including a plurality of first interdigital transducer (IDT) electrodes spaced apart from each other; a second resonator formed on the second region of the piezoelectric substrate and including a plurality of second IDT electrodes spaced apart from each other; and a bus bar formed on the step region of the piezoelectric substrate and shared by the first and second resonators, wherein the piezoelectric substrate has different thicknesses in the first and second regions, and a surface of the step region connecting the first and second regions forms an angle of 60 degrees or less with an upper surface of the first or second region.

In some embodiments, the bus bar may be formed to completely cover the upper surface of the step region.

In some embodiments, the k² value of the first resonator and the k² value of the second resonator may be different from each other.

In some embodiments, a conductive pad may further be formed on the bus bar.

In some embodiments, the surface of the step region may include irregularities.

In some embodiments, at least one energy confinement layer may be provided between the support substrate and the piezoelectric substrate.

In some embodiments, the at least one energy confinement layer may include a high acoustic velocity layer disposed on the support substrate and a low acoustic velocity layer disposed between the high acoustic velocity layer and the piezoelectric substrate.

In some embodiments, the support substrate may further include a cavity formed therein, at least partially overlapping, in a vertical direction, with the first region, the second region, or the step region.

According to another embodiment of the present invention, an acoustic wave device including resonators formed on piezoelectric substrates having different heights comprises: a support substrate; a piezoelectric substrate disposed on the support substrate and including a first region, a second region, and a step region disposed between the first and second regions; a first resonator formed on the first region of the piezoelectric substrate and including a plurality of first IDT electrodes spaced apart from each other; and a second resonator formed on the second region of the piezoelectric substrate and including a plurality of second IDT electrodes spaced apart from each other, wherein the piezoelectric substrate has different thicknesses in the first and second regions, and a surface of the step region includes surface irregularities.

In some embodiments, the surface of the step region connecting the first and second regions forms an angle of 60 degrees or less with an upper surface of the first or second region.

In some embodiments, a bus bar shared by the first and second resonators is formed on the step region of the piezoelectric substrate, and a conductive pad is formed on the bus bar.

According to another embodiment of the present invention, a method for manufacturing an acoustic wave device including resonators formed on piezoelectric substrates having different heights comprises: providing a piezoelectric substrate disposed on a support substrate; forming a mask pattern on the piezoelectric substrate; etching the piezoelectric substrate using the mask pattern to form, in the piezoelectric substrate, a first region having a first thickness, a second region having a second thickness smaller than the first thickness, and a step region connecting the first and second regions; and forming a first resonator and a second resonator on the first and second regions, respectively, wherein a surface of the step region connecting the first and second regions forms an angle of 60 degrees or less with an upper surface of the first or second region.

In some embodiments, forming the mask pattern on the piezoelectric substrate may include forming a sidewall of the mask pattern for defining the step region at an angle of 90 degrees or less relative to an upper surface of the piezoelectric substrate.

In some embodiments, forming the mask pattern on the piezoelectric substrate may include forming surface irregularities on a surface profile of the mask pattern.

The specific details of other embodiments are described in the following detailed description and drawings.

### Effects of the invention

In the acoustic wave device including resonators formed on piezoelectric substrates having different heights according to embodiments of the present invention, the k² value of the acoustic wave device can be varied by adjusting the thickness difference between different regions of the piezoelectric substrate.

By forming the step region connecting different regions at an angle of 60 degrees or less, the reliability of a metal layer formed to cover the step region can be improved.

The effects of the present invention are not limited to those described above, and other effects not explicitly mentioned herein will be apparent to those skilled in the art from the description of the appended claims.

### BRIEF DESCRIPTION OF THE DRAWINGS

FIG. 1 is a diagram illustrating an acoustic wave device including resonators formed on piezoelectric substrates having different heights according to an embodiment of the present invention.

FIG. 2 is a cross-sectional view of the acoustic wave device shown in FIG. 1.

FIGS. 3 and 4 are diagrams for explaining a step region (30) in the acoustic wave device shown in FIGS. 1 and 2.

FIG. 5 is a diagram illustrating the reliability of conductive pads and bus bars depending on the angle of the step region in the acoustic wave device including resonators formed on piezoelectric substrates having different heights according to an embodiment of the present invention.

FIGS. 6A and 6B are diagrams illustrating the difference in k² values according to the thickness difference between a first region and a second region in the acoustic wave device including resonators formed on piezoelectric substrates having different heights according to an embodiment of the present invention.

FIG. 7 is a diagram illustrating surface irregularities formed on the surface of a step region in the acoustic wave device including resonators formed on piezoelectric substrates having different heights according to an embodiment of the present invention.

FIG. 8 is a diagram illustrating an acoustic wave device including resonators formed on piezoelectric substrates having different heights according to another embodiment of the present invention.

FIGS. 9 to 12 are diagrams illustrating a method for manufacturing an acoustic wave device including resonators formed on piezoelectric substrates having different heights according to an embodiment of the present invention.

### EMBODIMENTS OF THE INVENTION

The advantages and features of the present invention, and the methods of achieving them, will become apparent from the following detailed description of exemplary embodiments with reference to the accompanying drawings. However, the present invention is not limited to the embodiments disclosed herein but may be embodied in various different forms. The embodiments are provided so as to fully convey the scope of the invention to those skilled in the art and to ensure a complete understanding of the disclosure. The scope of the invention is defined only by the claims.

Throughout the specification, the same reference numerals refer to the same components.

When an element is referred to as being “connected to” or “coupled to” another element, it can be directly connected or coupled to the other element, or indirectly connected or coupled thereto with one or more intervening elements. In contrast, when an element is referred to as being “directly connected to” or “directly coupled to” another element, there are no intervening elements present. The term “and/or” includes any and all combinations of the associated items.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. The terms “comprises” and/or “comprising,” when used in this specification, specify the presence of stated features, integers, steps, operations, elements, and/or components, but do not preclude the presence or addition of one or more other features, integers, steps, operations, elements, and/or components.

Although terms such as “first,” “second,” and the like may be used to describe various elements, such terms are used merely for convenience of distinction and do not imply any limitation or order. Thus, a “first” element may also be referred to as a “second” element within the technical scope of the invention.

Unless otherwise defined, all terms used herein (including technical and scientific terms) have the same meaning as commonly understood by one of ordinary skill in the art to which the invention pertains. Terms defined in commonly used dictionaries are to be interpreted as having meanings consistent with their contextual use in the relevant art and are not to be interpreted in an idealized or overly formal sense unless expressly so defined herein.

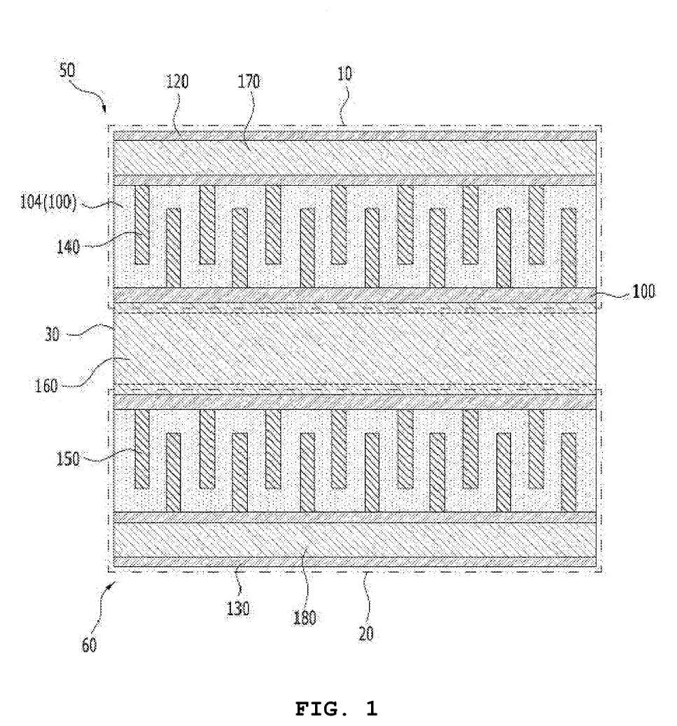

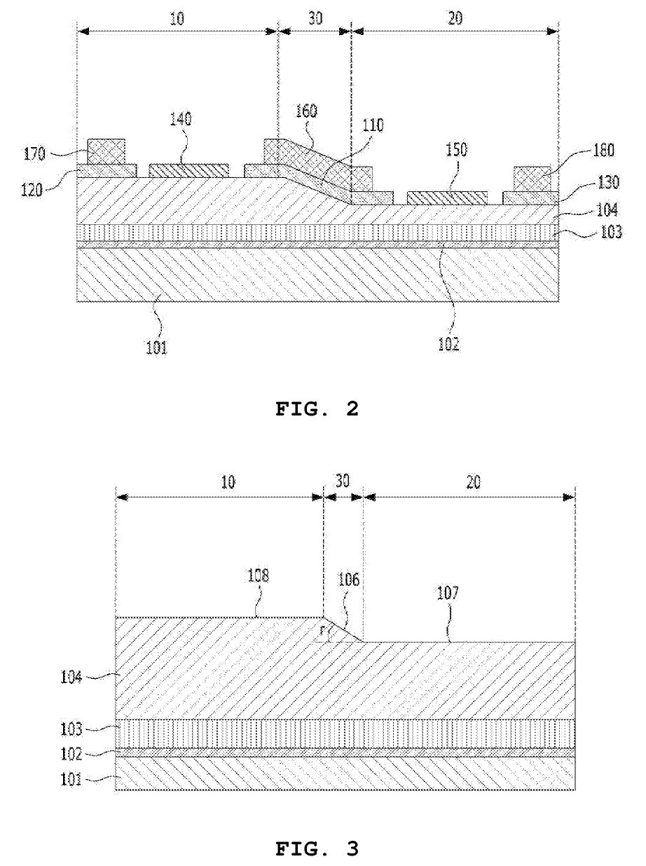

FIG. 1 is a diagram illustrating an acoustic wave device including resonators formed on piezoelectric substrates having different heights according to an embodiment of the present invention, and FIG. 2 is a cross-sectional view of the acoustic wave device shown in FIG. 1.

Referring to FIGS. 1 and 2, the acoustic wave device including resonators formed on piezoelectric substrates having different heights according to the embodiment of the present invention may include a support substrate 101, a high acoustic velocity layer 102, a low acoustic velocity layer 103, and a piezoelectric substrate 104. A first resonator 50 may be formed in a first region 10 of the piezoelectric substrate 104, and a second resonator 60 may be formed in a second region 20 thereof.

The first resonator 50 may include a plurality of first IDT electrodes 140 extending toward each other from a first bus bar 110 and a second bus bar 120 extending in the longitudinal direction. A conductive pad 170 may be formed on the second bus bar 120.

Similarly, the second resonator 60 may include a plurality of second IDT electrodes 150 extending toward each other from the first bus bar 110 and a third bus bar 130 extending in the longitudinal direction. A conductive pad 180 may be formed on the third bus bar 130.

The support substrate 101 may include, for example, a silicon substrate, a sapphire substrate, a quartz substrate, or a glass substrate, and may physically support the piezoelectric substrate 104 and the resonators formed thereon.

Energy confinement layers 102 and 103 may be formed on the support substrate 101. The energy confinement layers 102 and 103 may include at least one of a high acoustic velocity layer 102 that propagates an acoustic velocity higher than that of the elastic waves transmitted through the piezoelectric substrate 104, and a low acoustic velocity layer 103 that propagates a lower acoustic velocity.

The high acoustic velocity layer 102 may include at least one material selected from aluminum nitride, aluminum oxide, silicon nitride, silicon oxynitride, or silicon. The low acoustic velocity layer 103 may include at least one known material such as silicon oxide, glass, or silicon oxynitride.

The piezoelectric substrate 104 may include a piezoelectric element that generates an elastic wave from a signal applied to the plurality of IDT electrodes 140 and 150, and may include, for example, LiTaO₃ (LT) or LiNbO₃ (LN).

The piezoelectric substrate 104 may define a first region 10 and a second region 20, as shown in FIG. 2, where the thicknesses of the first region 10 and the second region 20 differ from each other. The thickness of each region refers to the distance from the upper surface of the low acoustic velocity layer 103 (i.e., the lower layer of the piezoelectric substrate 104) to the upper surface of each region 10 or 20.

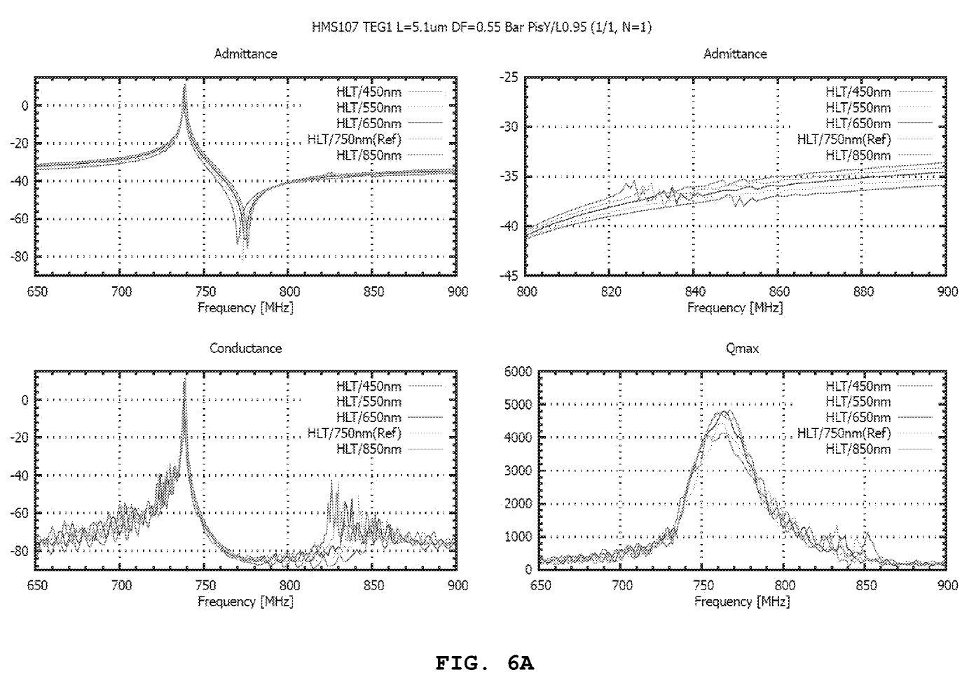

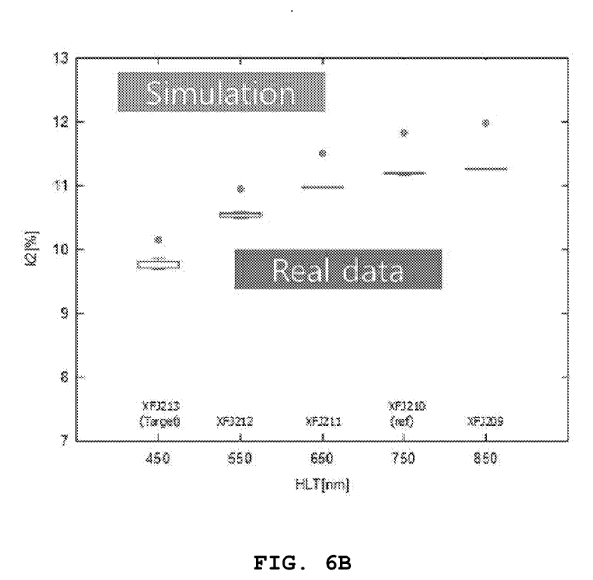

In one embodiment, the thickness of the first region 10 may be 750 nm, and the thickness of the second region 20 may be 450 nm. The thickness difference between the first and second regions may be formed to be at least 100 nm and up to 900 nm, sufficient to provide different k² values between the first resonator 50 and the second resonator 60. Details regarding this relationship will be described later with reference to FIGS. 6A and 6B.

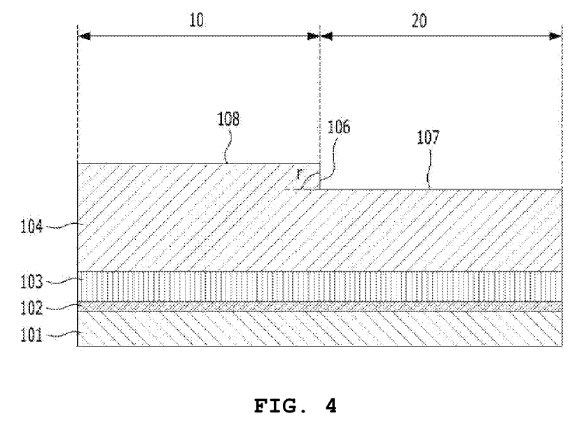

A step region 30 may be defined between the first region 10 and the second region 20. The step region 30 may be located at the boundary area between the regions of different thicknesses and serve as a connection region therebetween. As shown in FIG. 3, the surface 106

of the step region 30 may form an angle r smaller than a right angle with respect to the upper surface 107 or 108 of the first or second region, preferably less than 60 degrees.

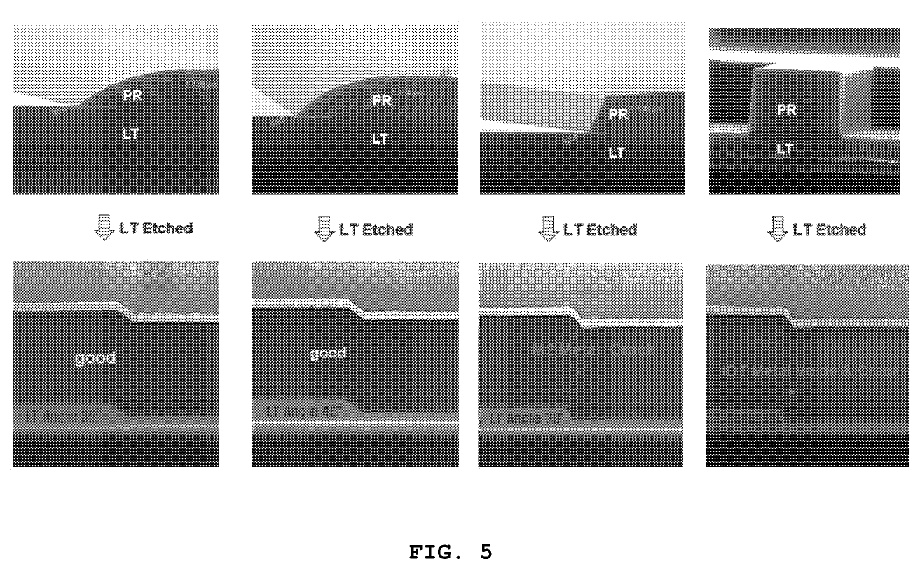

FIGS. 3 and 4 are diagrams illustrating the step region 30 in the acoustic wave device shown in FIGS. 1 and 2.

Referring to FIG. 3, bus bars 110 and IDT electrodes 140 and 150 formed on the piezoelectric substrate 104 are omitted for clarity. As described above, the surface 106 of the step region 30 may form an angle r smaller than 90 degrees, preferably 60 degrees or less, relative to the upper surface 107 or 108 of the first or second region.

A bus bar 110 and a conductive pad 160 formed on the bus bar 110 may be provided on the step region 30. The bus bar 110 may be shared between the first resonator 50 and the second resonator 60 formed in the first region 10 and the second region 20, respectively.

When the bus bar 110 and conductive pad 160 are formed on the step region 30, a reliability issue of the bus bar 110 and conductive pad 160 may occur. Specifically, when the step region 30 is sharply formed at 90 degrees—at the boundary of piezoelectric thin films of different thicknesses, as shown in Fig.4—voids may be formed in the bus bar 110 and conductive pad 160 covering the step region, and diffusion of elements such as gold in the conductive pad 160 into adjacent metal layers may occur.

To address this problem, the acoustic wave device according to an embodiment of the present invention forms the step region 30 at an angle of 60 degrees or less, thereby preventing reliability degradation caused by void formation or metal diffusion in the bus bar 110 and the conductive pad 160 covering the step region.

Referring to FIG. 5, the relationship between the angle r of the step region 30 and the reliability of the conductive pad and the bus bar in the acoustic wave device including resonators formed on piezoelectric substrates of different heights according to an embodiment of the present invention is illustrated.

When the angle r formed between the surface 106 of the step region 30 and the upper surface 107 or 108 of the first or second region is 60 degrees or less — for example, 45 degrees or 32 degrees — no cracks or voids are formed in the bus bar 110 or the conductive pad 160 that covers the step region.

In contrast, when the angle r is 60 degrees or greater — for example, 70 degrees (where cracks occur in the conductive pad 160) or 90 degrees (where both voids and cracks occur in the bus bar 110) — reliability issues appear in the metal layers covering the step region 30.

Therefore, it can be observed that forming the step region 30 at an angle smaller than 60 degrees with respect to the upper surfaces of the first and second regions can prevent cracks and voids in the metal layers, thereby improving reliability.

FIGS. 6A and 6B illustrate the difference in k² values depending on the thickness difference between the first region and the second region in the acoustic wave device including resonators formed on piezoelectric substrates of different heights according to an embodiment of the present invention.

Referring to FIG. 6A, the admittance and conductance characteristics of the acoustic wave device are shown for various thicknesses of the first region 10 — specifically, 450 nm, 550 nm, 650 nm, 750 nm, and 850 nm — while the second region 20 is maintained at a constant thickness of 450 nm. Accordingly, the characteristics in FIG. 6A reflect variations in admittance and conductance according to the thickness difference between the two regions.

As the thickness difference between the first region 10 and the second region 20 increases, the interval between the resonance frequency and the anti-resonance frequency increases. The same trend is observed in FIG. 6B, which shows changes in the k² value. That is, as the thickness of the first region 10 increases from 450 nm to 850 nm while the second region 20 remains at 450 nm, both simulation and measurement results confirm that the k² value increases — consistent with the changes observed in FIG. 6A.

This demonstrates that, in the acoustic wave device including resonators formed on piezoelectric substrates of different heights according to the present invention, the k² value can be controlled by adjusting the thickness difference between the first and second regions.

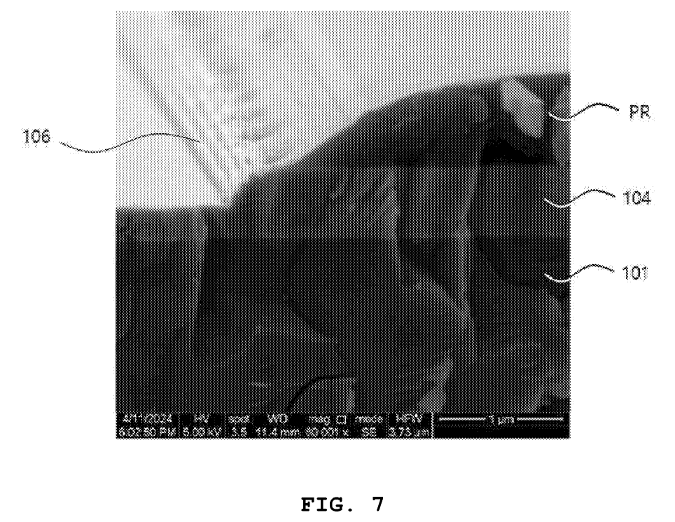

In some embodiments of the present invention, the surface 106 of the step region 30 may have a roughened or uneven texture. This is illustrated in FIG. 7, which shows an electron microscope image of the surface 106 of the step region 30.

During the formation of the step region 30, a photoresist (PR) mask layer may be formed on the first region 10, and a portion of the second region 20 may be etched away. During exposure, light scattering and reflection may cause a Standing Wave Effect (SWE), which induces variations in the concentration of photo acid compounds (PAC) or photo acid generators (PAG), resulting in an uneven photoresist profile.

Such an uneven profile of the photoresist mask is transferred to the etched surface 106 of the step region 30, thereby producing the irregular pattern observed in FIG. 7.

The roughened surface 106 of the step region 30 can minimize the influence of bulk waves that may occur due to the thickness difference between the first and second regions. Specifically, bulk waves propagating inside the piezoelectric substrate 104 may be reflected toward the first and second resonators 50 and 60 by the boundary surface. This reflection effect becomes more pronounced when the surface 106 of the step region is vertical (i.e., 90 degrees).

However, since the step region 30 in the present invention is formed at an angle smaller than 60 degrees and may have a rough surface, the boundary surface scatters the bulk waves rather than reflecting them directly toward the resonators. Consequently, the influence of bulk wave reflection on the operation of the acoustic wave device is minimized.

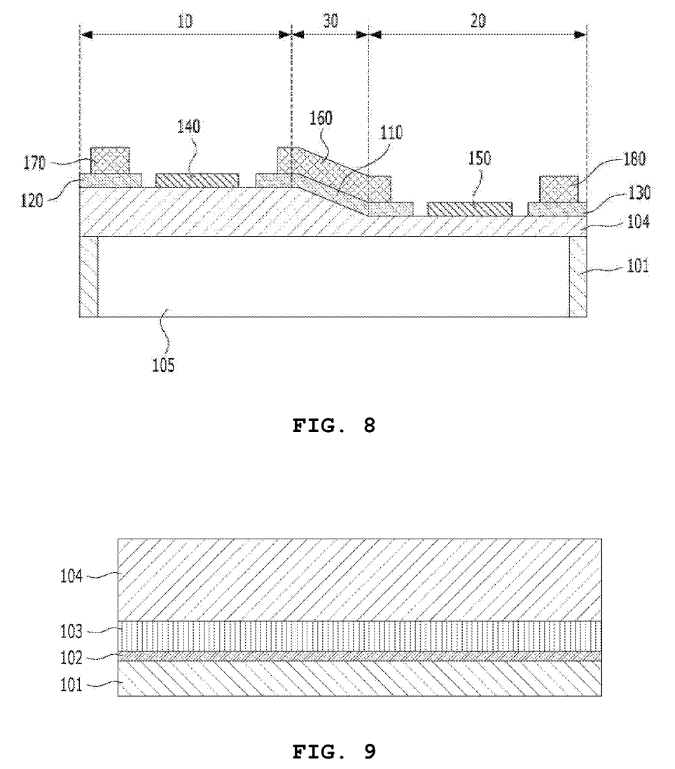

FIG. 8 is a diagram illustrating another embodiment of the acoustic wave device including resonators formed on piezoelectric substrates of different heights according to the present invention.

Referring to FIG. 8, the acoustic wave device may further include a cavity 105 formed inside the support substrate 101.

The cavity 105 may vertically overlap (in the thickness direction of the piezoelectric substrate 104) with all of the first region 10, the second region 20, and the step region 30 — or, in some cases, with at least one of them.

When the cavity 105 is formed inside the support substrate 101, the acoustic wave device can operate to transmit high-frequency, wideband signals (for example, at or above 2.7 GHz) through the propagation of Lamb waves (plate waves).

The cavity 105 may be formed by etching the support substrate 101. When the etching is performed after bonding the support substrate 101 with the piezoelectric substrate 104, the etching may continue until the lower surface of the piezoelectric substrate 104 is completely exposed, such that no portion of the support substrate 101 remains between the cavity 105 and the piezoelectric substrate 104.

FIGS. 9 to 12 are diagrams illustrating a method of manufacturing the acoustic wave device including resonators formed on piezoelectric substrates of different heights according to an embodiment of the present invention.

Referring to FIG. 9, a piezoelectric substrate 104 disposed on a support substrate 101 is provided. The substrate may have a stacked structure in which a high acoustic velocity layer 102, a low acoustic velocity layer 103, and the piezoelectric substrate 104 are sequentially formed, as shown in FIG. 7, though at least one of the high or low acoustic velocity layers may be omitted. In another embodiment, a piezoelectric substrate 104 supported by a support substrate 101 having a cavity 105, as shown in FIG. 8, may be provided.

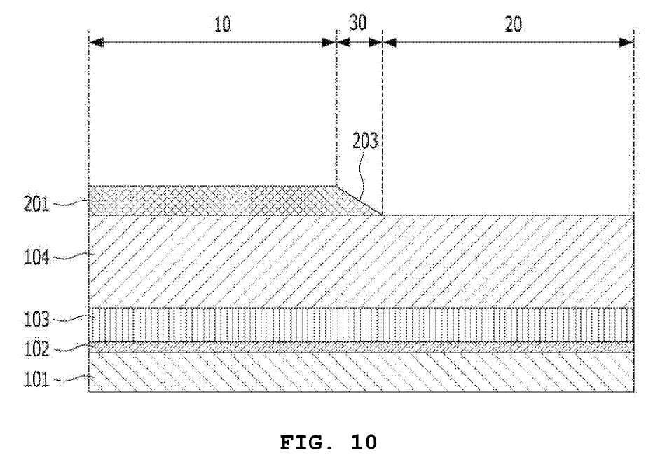

As shown in FIG. 10, a mask pattern 201 is formed on a piezoelectric substrate 104. The mask pattern 201 may include, for example, a photoresist. When the mask pattern 201 is formed through exposure and development processes after the formation of the mask film, the sidewall 203 of the mask pattern 201 having an angle of 90 degrees or less with respect to the upper surface of the piezoelectric substrate 104 may be disposed within the step region 30 described above.

In other words, when etching the piezoelectric substrate 104 using the mask pattern 201 as an etching mask, it is preferable that the mask pattern sidewall 203 is located within the step region 30 rather than across the boundary of the step region 30.

To realize the angle r in the step region, the sidewall 203 of the mask pattern 201 is preferably tapered, forming an angle smaller than 90 degrees relative to the surface of the piezoelectric substrate 104. For example, during exposure, a defocused exposure intentionally offset toward the upper surface of the mask may be applied to form the tapered sidewall 203.

Meanwhile, the angle formed by the sidewall 203 of the mask pattern 201 with the upper surface of the piezoelectric substrate 104 may be described with reference to FIG. 5. As a result confirmed through the experiment, in order to form the angle r of the stepped region 30 at 32 degrees, the sidewall 203 of the mask pattern 201 forming 36.6 degrees with the piezoelectric substrate 104 should be formed, and in order to form the angle r of the stepped region 30 at 45 degrees with the piezoelectric substrate 104, the sidewall 203 of the mask pattern 201 forming 45 degrees with the piezoelectric substrate 104 needs to be formed.

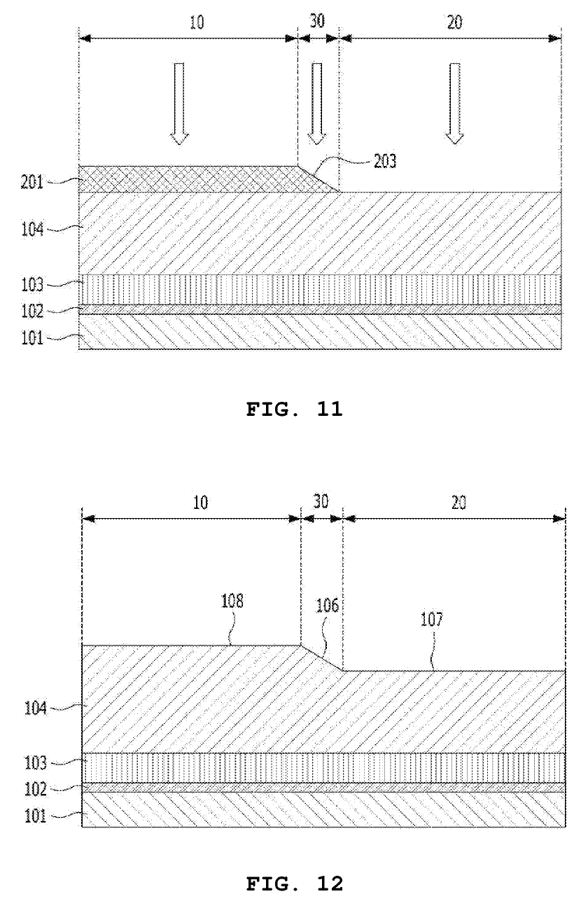

Referring to FIGS. 11 and 12, the second region 20 and the step region 30 of the piezoelectric substrate 104 are etched using the mask pattern 201 as an etching mask. The etching may be performed by a dry etching process. As explained above, the angle of the sidewall 203 of the mask pattern 201 determines the shape of the step surface 106, which is formed at an angle of 60 degrees or less.

Finally, referring again to FIGS. 1 and 2, the first and second resonators 50 and 60 are formed on the first region 10, the second region 20, and the step region 30 of the piezoelectric substrate 104. The shared bus bar 110 between the two resonators may be formed to completely cover the surface 106 of the step region 30.

By forming the surface 106 of the step region 30 at an angle of 60 degrees or less relative to the upper surfaces 107 and 108 of the piezoelectric substrate 104, voids or metal diffusion that could otherwise occur in the bus bar 110 or the conductive pad 160 are effectively prevented, thereby improving the overall reliability of the acoustic wave device.

As described above, the embodiment of the present invention has been described with reference to the accompanying drawings, but those of ordinary skill in the technical field to which the present invention belongs will understand that the present invention may be implemented in other specific forms without changing its technical idea or essential features. Therefore, it should be understood that the embodiments described above are exemplary and not limited in all respects.

What is claimed is:

1. An acoustic wave device comprising:
a support substrate;
a piezoelectric substrate disposed on the support substrate and including a first region, a second region, and a step region disposed between the first region and the second region;
a first resonator formed on the first region of the piezoelectric substrate and including a plurality of first interdigital transducer (IDT) electrodes spaced apart from each other;
a second resonator formed on the second region of the piezoelectric substrate and including a plurality of second IDT electrodes spaced apart from each other; and
a bus bar formed on the step region of the piezoelectric substrate and shared by the first and second resonators,
wherein the piezoelectric substrate has different thicknesses in the first and second regions, and a surface of the step region connecting the first and second regions forms an angle of 60 degrees or less with an upper surface of the first or second region.

2. The acoustic wave device according to claim 1, wherein the bus bar is formed to completely cover an upper surface of the step region.

3. The acoustic wave device according to claim 1, wherein the first and second resonators have different k² values.

4. The acoustic wave device according to claim 1, further comprising a conductive pad formed on the bus bar.

5. The acoustic wave device according to claim 1, wherein the surface of the step region includes irregularities.

6. The acoustic wave device according to claim 1, further comprising at least one energy confinement layer disposed between the support substrate and the piezoelectric substrate.

7. The acoustic wave device according to claim 6, wherein the at least one energy confinement layer includes a high acoustic velocity layer disposed on the support substrate and a low acoustic velocity layer disposed between the high acoustic velocity layer and the piezoelectric substrate.

8. The acoustic wave device according to claim 1, further comprising a cavity formed within the support substrate so as to vertically overlap, at least in part, the first region, the second region, or the step region.

9. An acoustic wave device comprising:
a support substrate;
a piezoelectric substrate disposed on the support substrate and including a first region, a second region, and a step region disposed between the first and second regions;
a first resonator formed on the first region and including a plurality of first IDT electrodes spaced apart from each other; and
a second resonator formed on the second region and including a plurality of second IDT electrodes spaced apart from each other,
wherein the piezoelectric substrate has different thicknesses in the first and second regions, and a surface of the step region includes irregularities.

10. The acoustic wave device according to claim 9, wherein a surface of the step region connecting the first and second regions forms an angle of 60 degrees or less with an upper surface of the first or second region.

11. The acoustic wave device according to claim 10, further comprising a bus bar formed on the step region and shared by the first and second resonators, and a conductive pad formed on the bus bar.

12. The acoustic wave device according to claim 9, wherein the first and second resonators have different k² values.

13. The acoustic wave device according to claim 9, further comprising at least one energy confinement layer disposed between the support substrate and the piezoelectric substrate.

14. The acoustic wave device according to claim 13, wherein the at least one energy confinement layer includes a high acoustic velocity layer disposed on the support substrate and a low acoustic velocity layer disposed between the high acoustic velocity layer and the piezoelectric substrate.

15. The acoustic wave device according to claim 9, further comprising a cavity formed within the support substrate so as to vertically overlap, at least in part, the first region, the second region, or the step region.

16. A method of manufacturing an acoustic wave device comprising:
providing a piezoelectric substrate disposed on a support substrate;
forming a mask pattern on the piezoelectric substrate;
etching the piezoelectric substrate using the mask pattern to form a first region having a first thickness, a second region having a second thickness smaller than the first thickness, and a step region connecting the first and second regions; and
forming a first resonator and a second resonator respectively on the first and second regions,
wherein a surface of the step region connecting the first and second regions forms an angle of 60 degrees or less with an upper surface of the first or second region.

17. The method according to claim 16, wherein forming the mask pattern includes forming a sidewall of the mask pattern at an angle of 90 degrees or less with respect to an upper surface of the piezoelectric substrate to define the step region.

18. The method according to claim 16, wherein forming the mask pattern includes forming irregularities in a surface profile of the mask pattern.
